(19) United States
(12) Patent Application Publication
(10) Pub. No.: US 2023/0145857 A1
(43) Pub. Date: May 11, 2023

(54) SEMICONDUCTOR DEVICES

(71) Applicant: SAMSUNG ELECTRONICS CO., LTD., SUWONN-SI (KR)

(72) Inventors: HYERAN LEE, Hwaseong-Si (KR); Sohyun Park, Seoul (KR); Junhyeok Ahn, Suwon-Si (KR)

(21) Appl. No.: 17/935,119

(22) Filed: Sep. 25, 2022

(30) Foreign Application Priority Data
Nov. 5, 2021 (KR) 10-2021-0151290

(51) Int. Cl. H01L 27/108; G11C 5/06

(52) U.S. Cl. CPC H01L 27/10814; G11C 5/063

(57) ABSTRACT

A semiconductor device includes a conductive contact plug disposed on a substrate, a bit line structure disposed on the conductive contact plug, first and second spacers, and a capping pattern disposed on the first and second spacers. The conductive contact plug includes a lower portion that has a first width and an upper portion that has a second width narrower than the first width. The bit line structure includes a conductive structure and an insulation structure stacked in a vertical direction. The first and second spacers are stacked on a sidewall of the lower portion of the conductive contact plug in a horizontal direction. The capping pattern covers a sidewall of the upper portion of the conductive contact plug. The first spacer directly contacts the sidewall of the lower portion of the conductive contact plug and includes air.

### CROSS-REFERENCE TO RELATED APPLICATION

This application claims priority under 35 U.S.C. § 119 from Korean Patent Application No. 10-2021-0151290, filed on Nov. 5, 2021 in the Korean Intellectual Property Office, the contents of which are herein incorporated by reference in their entirety.

### TECHNICAL FIELD

Embodiments of the present disclosure are directed to a semiconductor device. More particularly, embodiments of the present disclosure are directed to a DRAM device.

### DISCUSSION OF RELATED ART

In a DRAM device, a conductive contact plug may be formed under a bit line structure to contact an active pattern, and a parasitic capacitance may occur between neighboring conductive pads. Thus, it is desired to reduce the parasitic capacitance in the DRAM device.

### SUMMARY

Embodiments provide a semiconductor device that has increased characteristics.

According to embodiments of the inventive concepts, there is provided a semiconductor device. The semiconductor device includes a conductive contact plug disposed on a substrate, a bit line structure disposed on the conductive contact plug, first and second spacers, and a capping pattern disposed on the first and second spacers. The conductive contact plug includes a lower portion and an upper portion thereon, and the lower portion has a first width and the upper portion has a second width narrower than the first width. The bit line structure includes a conductive structure and an insulation structure stacked in a vertical direction substantially perpendicular to an upper surface of the substrate. The first and second spacers are stacked on a sidewall of the lower portion of the conductive contact plug in a horizontal direction substantially parallel to the upper surface of the substrate. The capping pattern covers a sidewall of the upper portion of the conductive contact plug. The first spacer directly contacts the sidewall of the lower portion of the conductive contact plug and includes air.

According to embodiments of the inventive concepts, there is provided a semiconductor device. The semiconductor device includes a conductive contact plug disposed on a substrate, a bit line structure disposed on the conductive contact plug, an air spacer, and a capping pattern disposed on a top end of the air spacer. The conductive contact plug includes a lower portion and an upper portion thereon, and the lower portion has a first width and the upper portion has a second width narrower than the first width. The bit line structure includes a conductive structure and an insulation structure stacked in a vertical direction substantially perpendicular to an upper surface of the substrate. The air spacer directly contacts a sidewall of the lower portion of the conductive contact plug and includes air.

According to embodiments of the inventive concepts, there is provided a semiconductor device. The semiconductor device includes an active pattern disposed on a substrate, an isolation pattern disposed on the substrate, a gate structure, a conductive pad, a conductive contact plug, a bit line structure, first and second spacers, a capping pattern, an insulation pattern, a spacer structure, a contact plug structure, and a capacitor. The isolation pattern covers a sidewall of the active pattern. The gate structure extends in a first direction substantially parallel to an upper surface of the substrate, and is disposed in upper portions of the active pattern and the isolation pattern. The conductive pad is formed on the active pattern and the isolation pattern. The conductive contact plug extends through the conductive pad and contacts a central upper surface of the active pattern. The conductive contact plug includes a lower portion and an upper portion thereon, and the lower portion has a first width and the upper portion has a second width narrower than the first width. The bit line structure is formed on the conductive contact plug and the conductive pad, and extends in a second direction substantially parallel to the upper surface of the substrate and substantially perpendicular to the first direction. The first and second spacers are stacked on a sidewall of the lower portion of the conductive contact plug in a horizontal direction substantially parallel to the upper surface of the substrate. The capping pattern is formed on the first and second spacers, and covers a sidewall of the upper portion of the conductive contact plug. The insulation pattern is formed on the capping pattern. The spacer structure is formed on the capping pattern and the insulation pattern, and on a sidewall of the bit line structure. The contact plug structure is formed on the conductive pad. The capacitor is formed on the contact plug structure. The first spacer directly contacts the sidewall of the lower portion of the conductive contact plug and includes air.

In a semiconductor device in accordance with embodiments, an air spacer is formed between the conductive contact plug under the bit line structure and the conductive pad adjacent to the conductive contact plug, and thus a parasitic capacitance between the conductive contact plug and the conductive pad decreases.

### BRIEF DESCRIPTION OF THE DRAWINGS

FIGS. 1 to 24 are plan views and cross-sectional views that illustrate a method of manufacturing a semiconductor device in accordance with embodiments.

FIGS. 25 to 28 are cross-sectional views that illustrate a method of manufacturing a semiconductor device in accordance with embodiments.

### DETAILED DESCRIPTION

Aspects and features of a gate structure and a method of forming the same, and a semiconductor device that includes the gate structure and a method of manufacturing the same in accordance with embodiments will become readily understood from detailed descriptions that follow, with reference to the accompanying drawings.

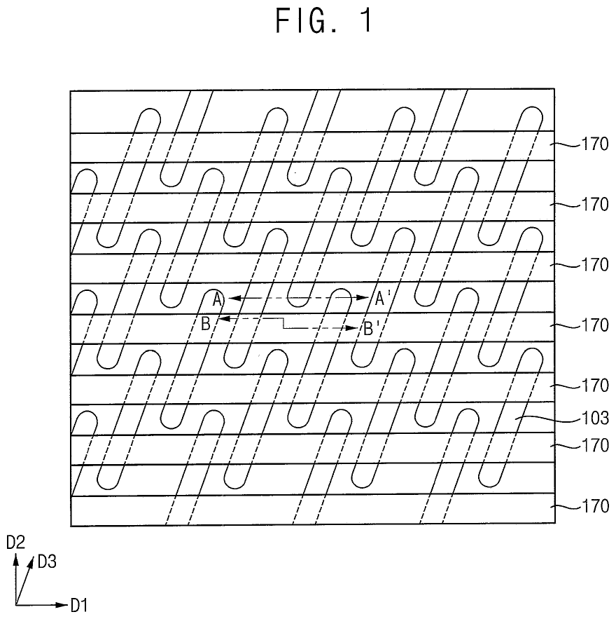

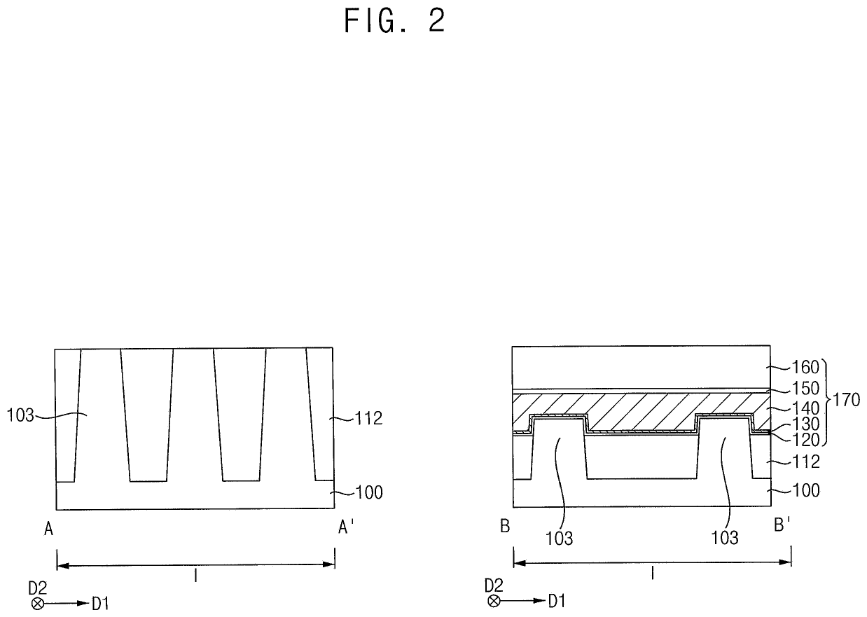

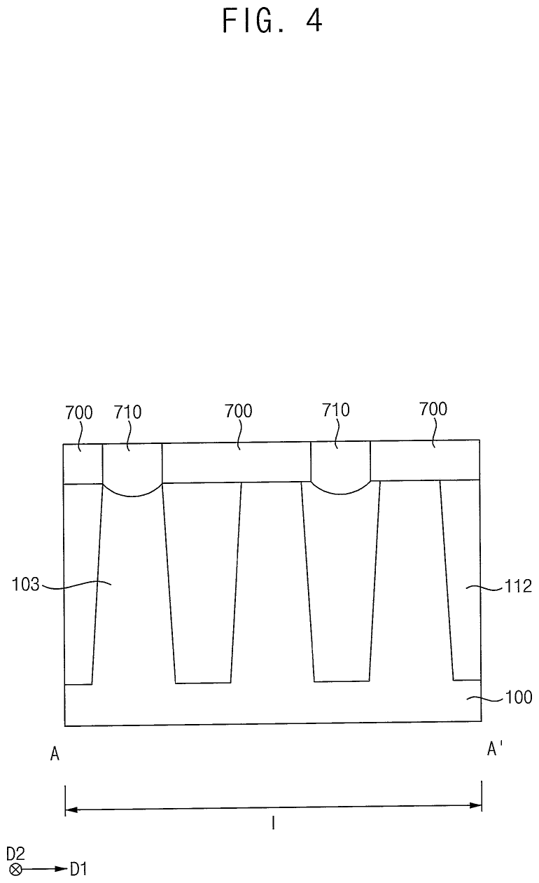

FIGS. 1 to 24 are plan views and cross-sectional views that illustrate a method of manufacturing a semiconductor device in accordance with embodiments. In particular, FIGS. 1, 3, 5, 9, 18 and 22 are plan views, FIG. 2 shows cross-sections taken along lines A-A′ and B-B′ of FIG. 1, and FIGS. 4, 6-8, 10-17, 19-21 and 23-24 show cross-sectional views taken along line A-A′ of corresponding plan views, respectively.

Hereinafter, in the specification, and not necessarily in the claims, two directions substantially parallel to an upper surface of a substrate and substantially perpendicular to each other may be referred to as first and second directions D1 and D2, respectively, and a direction substantially parallel to the upper surface of the substrate and having an acute angle with respect to the first and second directions D1 and D2 may be referred to as a third direction D3.

Referring to FIGS. 1 and 2, in an embodiment, an active pattern 103 is formed on a substrate 100, and an isolation pattern 112 is formed that covers a sidewall of the active pattern 103.

The substrate 100 includes at least one of silicon, germanium, or silicon-germanium, or a III-Vgroup compound semiconductor, such as GaP, GaAs, or GaSb. In embodiments, the substrate 100 is one of a silicon-on-insulator (SOI) substrate or a germanium-on-insulator (GOI) substrate.

The active pattern 103 is formed by removing an upper portion of the substrate 100 to form a first recess, and the active pattern 103 extends in the third direction D3. In embodiments, a plurality of active patterns 103 are spaced apart from each other in the first and second directions D1 and D2. The isolation pattern 112 is formed in the first recess, and includes an oxide, such as silicon oxide.

The active pattern 103 and the isolation pattern 112 are partially removed to form a second recess that extends in the first direction D1.

A gate structure 170 is formed in the second recess. The gate structure 170 includes a gate insulation pattern 120 disposed on a bottom and a sidewall of the second recess, a first barrier pattern 130 disposed on a portion of the gate insulation pattern 120 on the bottom and a lower sidewall of the second recess, a first conductive pattern 140 disposed on the first barrier pattern 130 and that fills a lower portion of the second recess, a second conductive pattern 150 disposed on the first barrier pattern 130 and an upper surface of the first conductive pattern 140, and a gate mask 160 disposed on an upper surface of the second conductive pattern 150 and an upper inner sidewall of the gate insulation pattern 120 and that fills an upper portion of the second recess. The first barrier pattern 130, the first conductive pattern 140 and the second conductive pattern 150 form a gate electrode.

The gate insulation pattern 120 includes an oxide, such as silicon oxide, the first barrier pattern 130 includes a metal nitride, such as titanium nitride or tantalum nitride, etc., the first conductive pattern 140 includes at least one of a metal, a metal nitride, a metal silicide, or doped polysilicon, etc., the second conductive pattern 150 includes doped polysilicon, and the gate mask 160 includes a nitride, such as silicon nitride.

In embodiments, the gate structure 170 extends in the first direction D1, and a plurality of gate structures 170 are spaced apart from each other in the second direction D2.

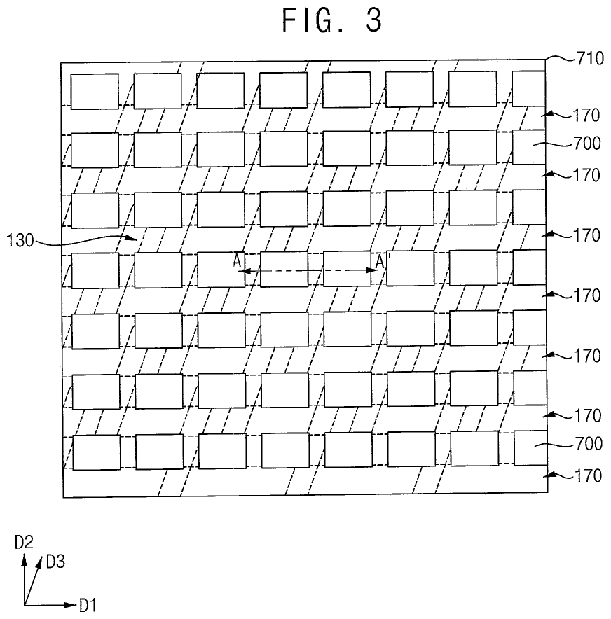

Referring to FIGS. 3 and 4, in an embodiment, a first pad 700 and a second pad 710 are formed on the substrate 100 on which the active pattern 103, the isolation pattern 112 and the gate structure 170 are formed thereon.

In embodiments, a first pad layer is formed on the substrate 100, the first pad layer is patterned to form a first opening that exposes upper surfaces of the active pattern 103, the isolation pattern 112 and the gate structure 170, and a second pad 710 is formed in the first opening.

The first pad 700 includes, for example, at least one of doped polysilicon, a metal such as tungsten or ruthenium, etc., a metal nitride such as titanium nitride or tantalum nitride, etc., or graphene. In an embodiment, the first pad 700 is a single layer that includes one of the above-mentioned materials. Alternatively, in an embodiment, the first pad 700 is a multi-layer structure that includes a plurality of layers, where each layer includes one of the above-mentioned materials, respectively.

The second pad 710 includes a nitride, such as silicon nitride.

In embodiments, the first opening includes a first portion that extends in the first direction D1 and a second portion that extends in the second direction D2, and the first portion and the second portion are connected with each other. Thus, the second pad 710 includes a first extension portion that extends in the first direction D1 and a second extension portion that extends in the second direction D2, and that are connected with each other. In embodiments, the second pad 710 forms a mesh pattern. In embodiments, a plurality of first pads 700 are spaced apart from each other in the first and second directions D1 and D2, and are arranged in a lattice pattern.

In embodiments, the first pad 700 overlaps in a vertical direction an end portion of each active pattern 103 that extends in the third direction D3 and a portion of the isolation pattern 112 adjacent thereto.

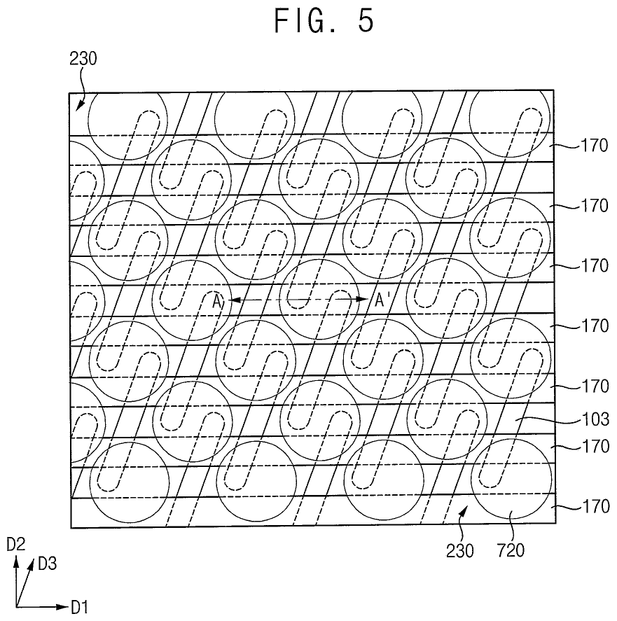

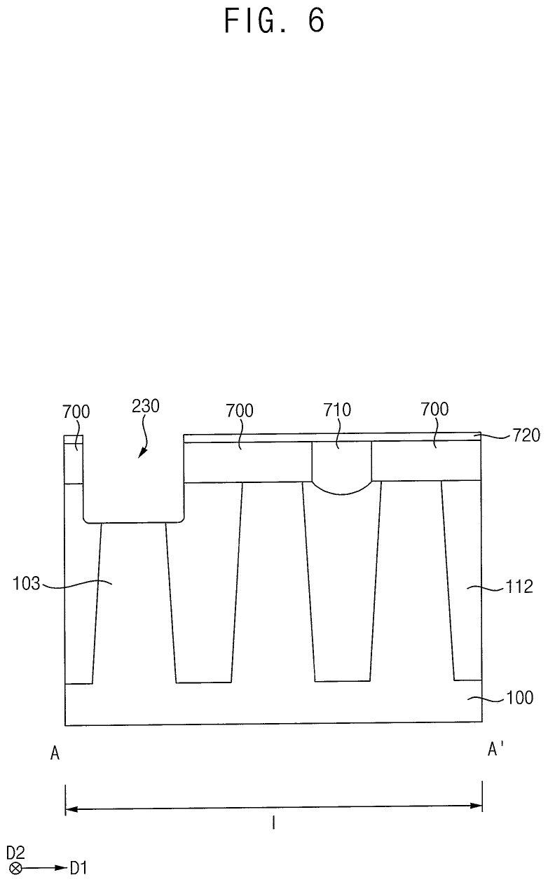

Referring to FIGS. 5 and 6, in an embodiment, a third pad layer is formed on the first and second pads 700 and 710, and is patterned to form a third pad 720, and the active pattern 103, the isolation pattern 112, and the gate mask 160 in the gate structure 170 are partially etched using the third pad 720 as an etching mask to form a second opening 230.

In embodiments, the third pad 720 has a shape of a circle or an ellipse in a plan view, and a plurality of third pads 720 are formed that are spaced apart from each other in the first and second directions D1 and D2. Each third pad 720 overlaps in the vertical direction end portions of the active patterns 103 that are adjacent in the first direction D1 and a portion of the isolation pattern 112 between the end portions of the active patterns 103. Each active pattern 103 has a first end and a second end that are opposite to each other in the third direction. In an embodiment, each third pad overlaps a first end of an active pattern 103 and a second end of the adjacent active pattern 103. The pad 720 includes a nitride, such as silicon nitride.

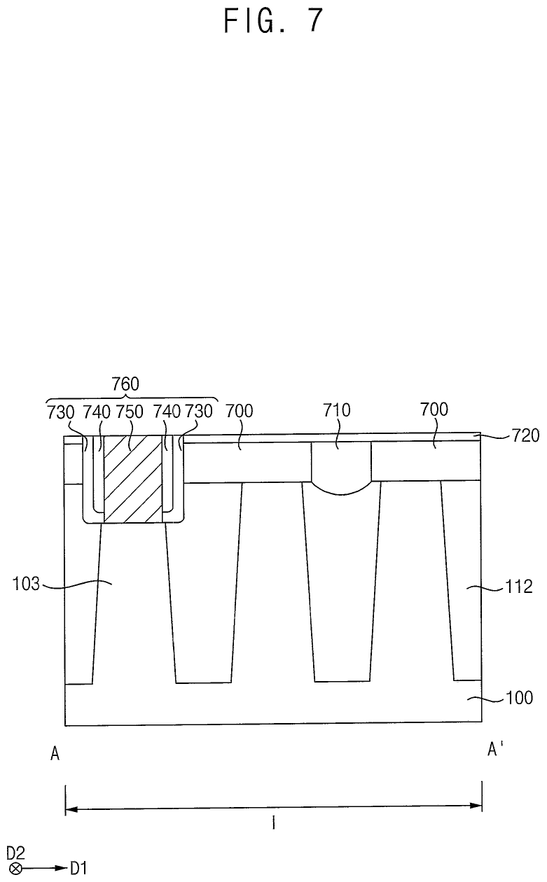

Referring to FIG. 7, in an embodiment, first and second spacers 730 and 740 and a first filling pattern 750 are formed in the second opening 230.

In embodiments, first and second spacer layers are sequentially formed on an inner wall of the second opening 230 and the third pad 720, and are anisotropically etched so that a first spacer 730 is formed on a sidewall of the second opening 230 and that a second spacer 740 is formed on the first spacer 730. A lowermost surface of the second spacer 740 may be covered by the first spacer 730.

The first spacer 730 may include a nitride, such as silicon nitride or a carbide, such as silicon oxycarbide, and the second spacer 740 includes, such as an oxide such as silicon oxide.

The first filling pattern 750 is formed in the second opening 230 by filling the second opening 230 in which the first and second spacers 730 and 740 are formed with a first filling layer, and performing an etch back process on the first filling layer.

The first and second spacers 730 and 740 and the first filling pattern 750 in the second opening 230 form a first filling structure 760.

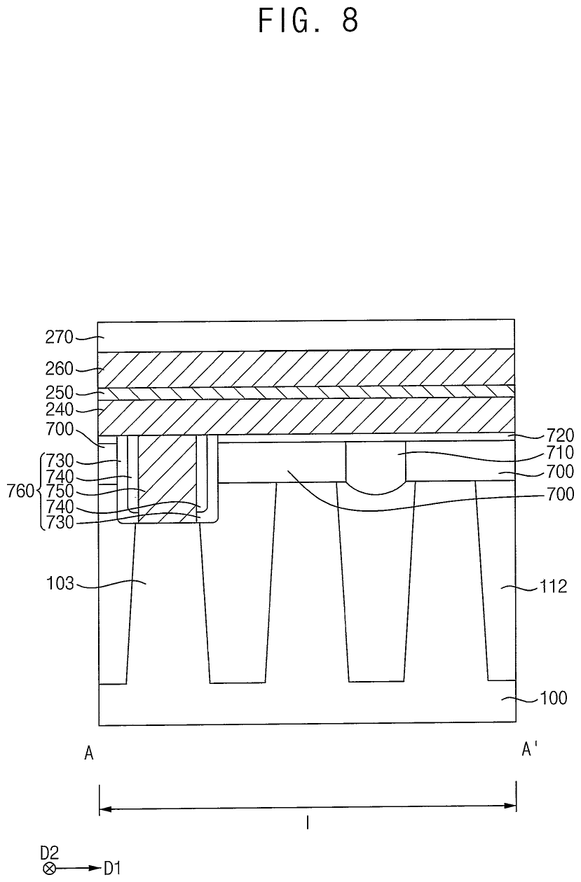

Referring to FIG. 8, in an embodiment, a third conductive layer 240, a second barrier layer 250, a fourth conductive layer 260 and a first mask layer 270 are sequentially stacked on the third pad 720 and the first filling structure 760, and the third conductive layer 240, the second barrier layer 250 and the fourth conductive layer 260 form a conductive layer structure.

The third conductive layer 240 includes, e.g., doped polysilicon, the second barrier layer 250 includes a metal silicon nitride, such as titanium silicon nitride, the fourth conductive layer 260 includes a metal, such as tungsten, and the first mask layer 270 includes a nitride, such as silicon nitride.

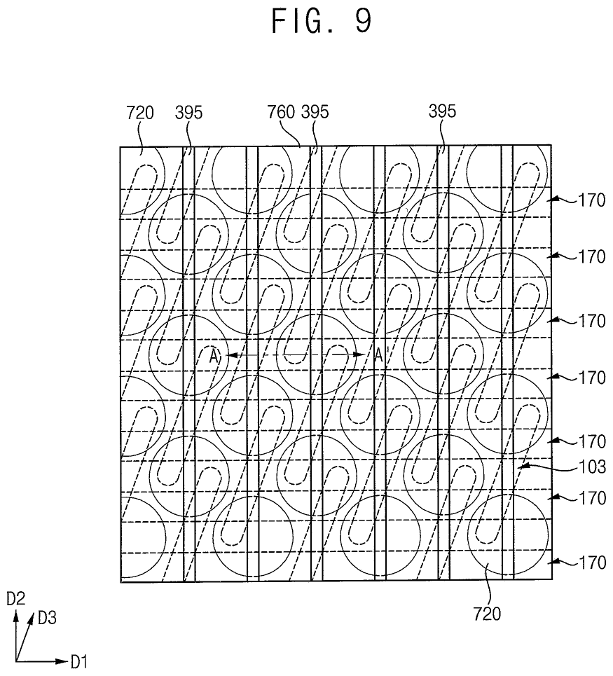

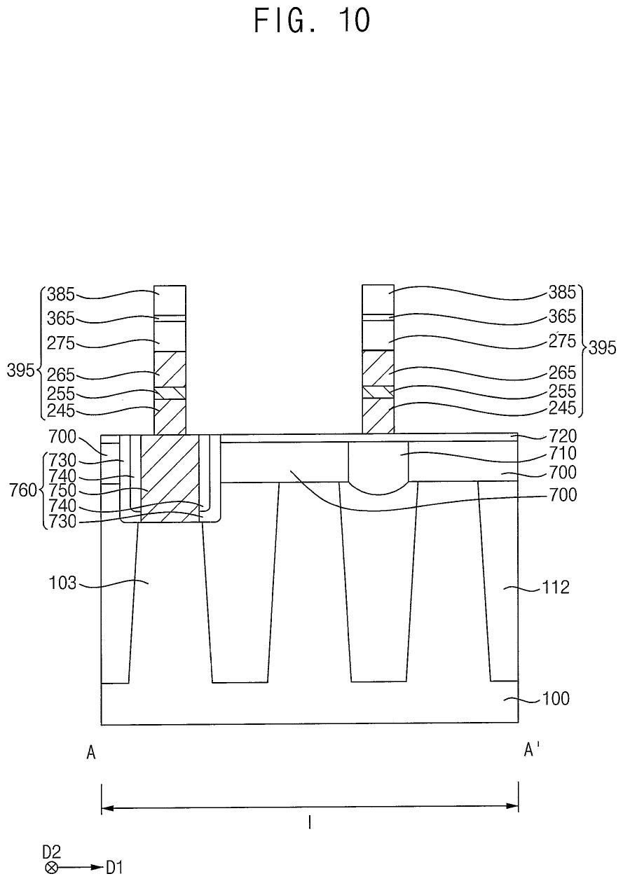

Referring to FIGS. 9 and 10, in an embodiment, a first etch stop layer and a first capping layer may be sequentially formed on the first mask layer 270. Each of the first etch stop layer and the first capping layer includes a nitride, such as silicon nitride.

The first capping layer is patterned to form a first capping pattern 385, and the first etch stop layer, the first mask layer 270, the fourth conductive layer 260, the second barrier layer 250 and the third conductive layer 240 are sequentially etched using the first capping pattern 385 as an etching mask.

By the etching process, a third conductive pattern 245, a second barrier pattern 255, a fourth conductive pattern 265, a first mask 275, a first etch stop pattern 365 and the first capping pattern 385 are sequentially stacked on the third pad 720 and the first filling structure 760.

Hereinafter, the third conductive pattern 245, the second barrier pattern 255, the fourth conductive pattern 265, the first mask 275, the first etch stop pattern 365 and the first capping pattern 385 may be referred to as a bit line structure 395. The bit line structure 395 includes a conductive structure that includes the third conductive pattern 245, the second barrier pattern 255 and the fourth conductive pattern 265, which are sequentially stacked, and an insulation structure stacked on the conductive structure and that includes the first mask 275, the first etch stop pattern 365 and the first capping pattern 385 In embodiments, the bit line structure 395 extends in the second direction D2 on the substrate 100, and a plurality of bit line structures 395 are spaced apart from each other in the first direction D1.

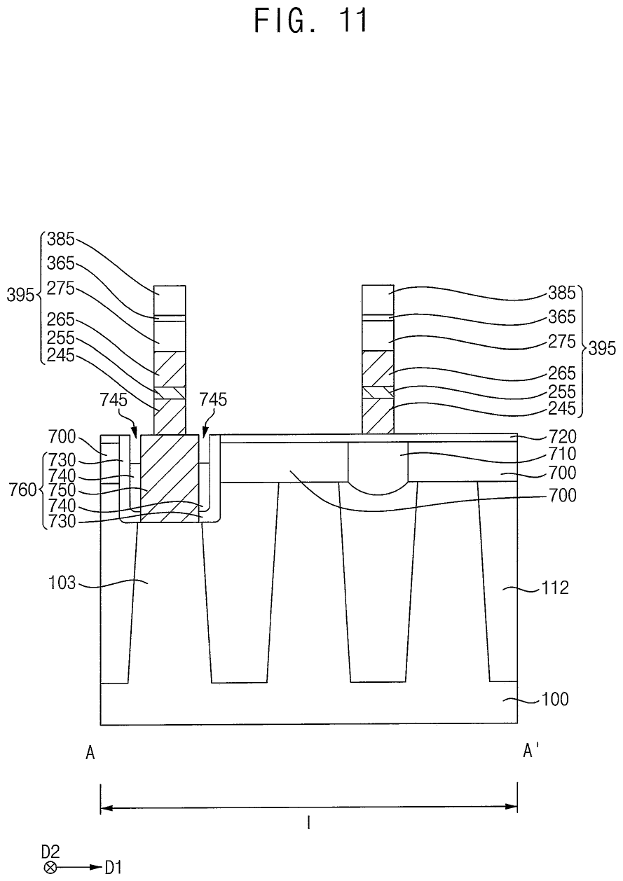

Referring to FIG. 11, in an embodiment, an upper portion of the second spacer 740 in the second opening 230 is removed to form a third recess 745.

Thus, an upper sidewall of the first filling pattern 750 is exposed by the third recess 745.

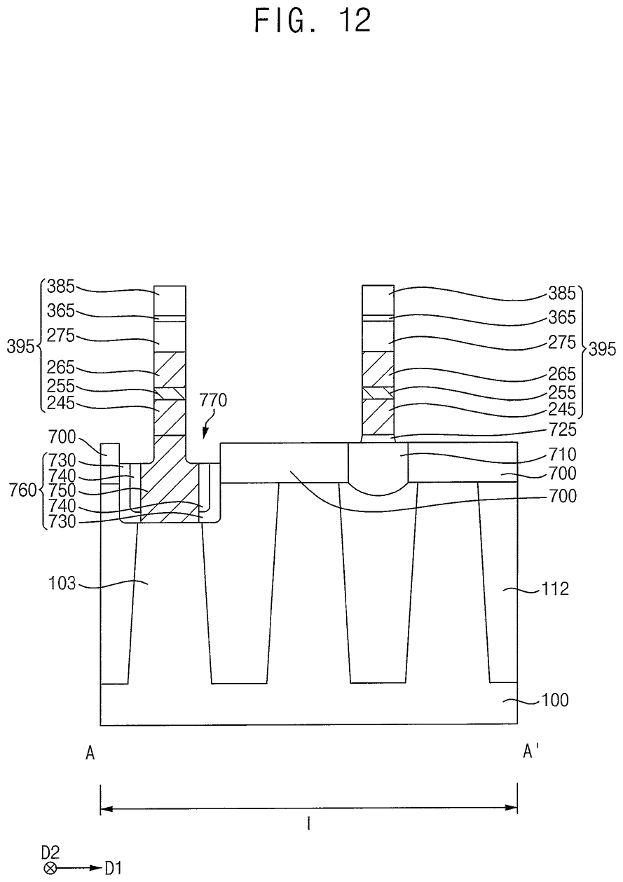

Referring to FIG. 12, in an embodiment, an upper portion of the first filling pattern 750 that is not covered by the bit line structure 395 and is exposed by the third recess 745 is removed by an etching process, and thus the first filling pattern 750 in the second opening 230 includes a relative wide lower portion and a relatively narrow upper portion.

The first filling pattern 750 includes a conductive material, and is formed between and in contact with a lower surface of the bit line structure 395 and an upper surface of the active pattern 103. The first filling pattern 750 may also be referred to as a conductive contact plug.

During an etching process, a portion of the first spacer 730 that is higher than an upper surface of the second spacer 740 and a portion of the third pad 720 that is not covered by the bit line structure 395 are also removed.

Thus, an upper sidewall of the second opening 230 is exposed, and a fourth recess 770 is formed at an upper portion of the initial second opening 230. In addition, a fourth pad 725 is formed under a portion of the bit line structure 395 outside of the second opening 230, and upper surfaces and upper side surfaces of the first pads 700 and upper surfaces of the second pads 710 are exposed.

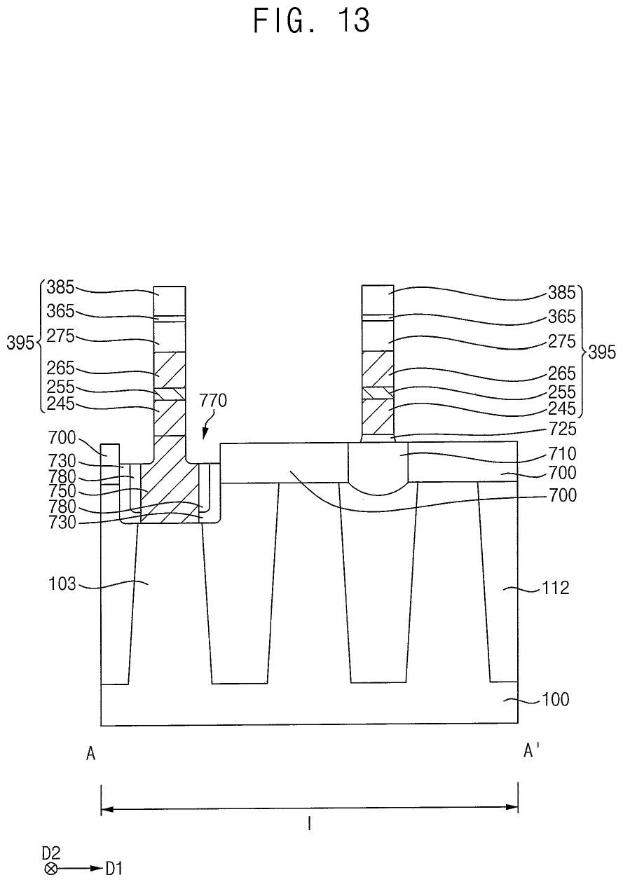

Referring to FIG. 13, in an embodiment, the second spacer 740 that remains in the second opening 230 is removed to form a fifth recess, and a first sacrificial pattern 780 is formed in the fifth recess.

The first sacrificial pattern 780 is formed by forming a first sacrificial layer on the bit line structure 395, the first spacer 730, the first, second and fourth pads 700, 710 and 725 and filling the fifth recess and performing an etch back process on the first sacrificial layer until an upper surface of the first spacer 730 is exposed. In some embodiments, a stripping process is further performed.

Thus, an upper surface of the first sacrificial pattern 780 is substantially coplanar with an upper surface of the first spacer 730.

In embodiments, the first sacrificial pattern 780 includes a pyrolysis material that is decomposed by heat.

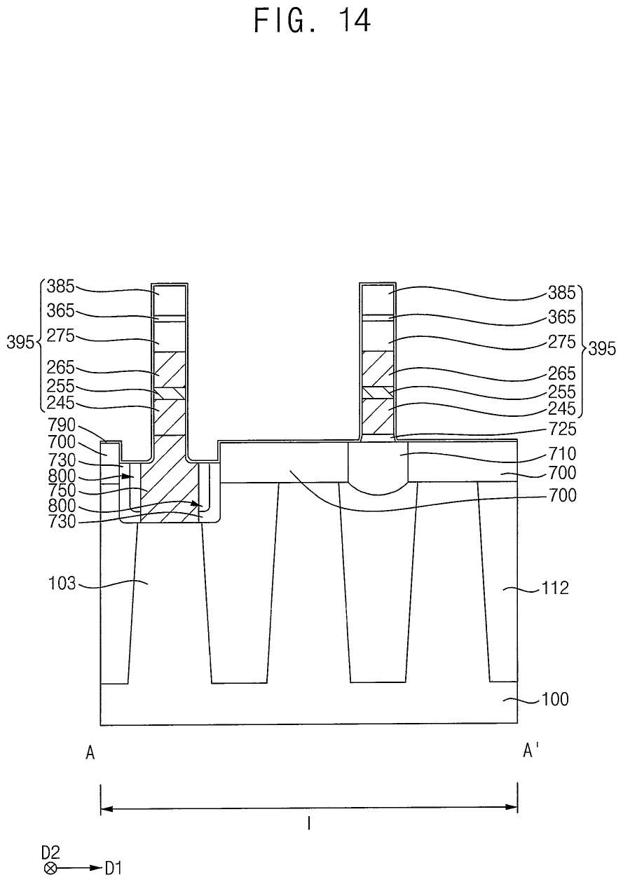

Referring to FIG. 14, in an embodiment, a second capping layer 790 is formed by, e.g., an ALD process on the bit line structure 395, the first filling pattern 750, the first spacer 730, the first sacrificial pattern 780, and the first, second and fourth pads 700, 710 and 725, and the substrate 100 is heated to remove the first sacrificial pattern 780.

As the first sacrificial pattern 780 is removed, a first air spacer 800 that is surrounded by a lower portion of the first filling pattern 750, the first spacer 730 and the second capping layer 790 is formed.

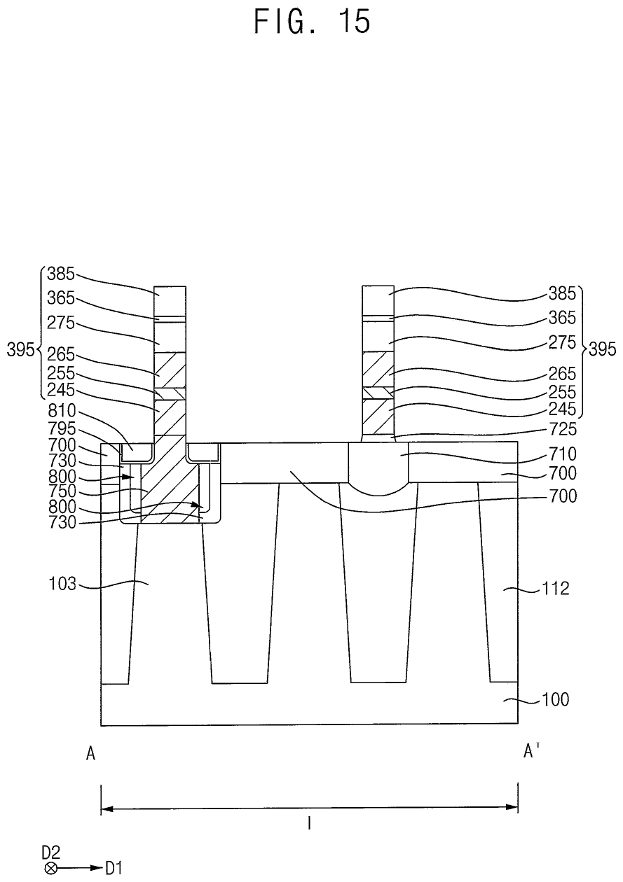

Referring to FIG. 15, in an embodiment, a second filling layer that fills the fourth recess 770 is formed on the second capping layer 790, and an upper portion of the second filling layer is removed by an etching process until upper surfaces of the first and second pads 700 and 710 are exposed.

During the etching process, a portion of the second capping layer 790 that is outside of the second opening 230, that is, outside of the fourth recess 770, is also removed, and thus an upper surface and a sidewall of the bit line structure 395, the upper surfaces of the first and second pads 700 and 710 and a sidewall of the fourth pad 725 are exposed.

Thus, a second capping pattern 795 remains on an inner wall of the fourth recess 770, and a second filling pattern 810 is formed on the second capping pattern 795. The first and second filling patterns 750 and 810, the first spacer 730, the first air spacer 800 and the second capping pattern 795 in the second opening 230 form a second filling structure.

The second filling pattern 810 includes a nitride, such as silicon nitride.

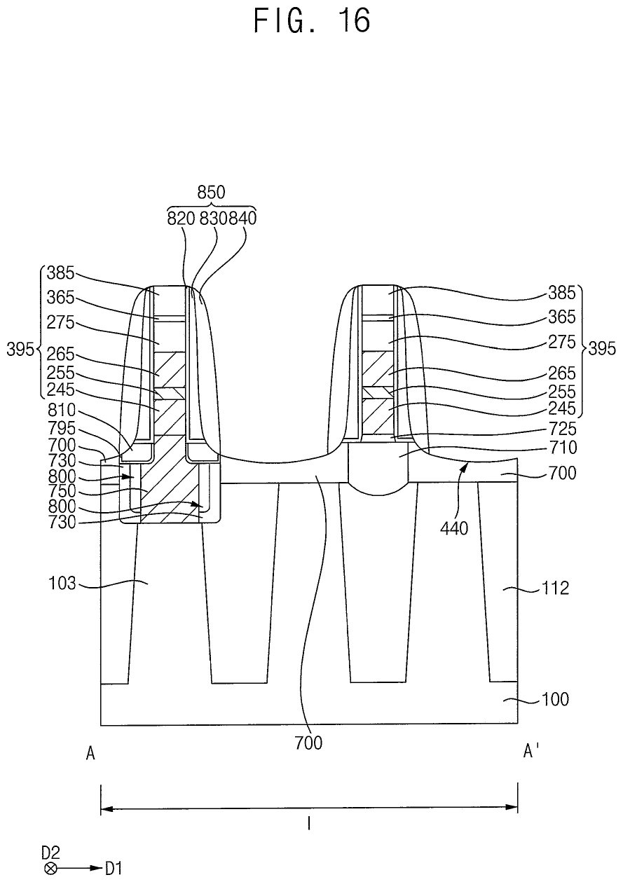

Referring to FIG. 16, in an embodiment, third and fourth spacer layers are sequentially stacked on the bit line structure 395, the first, second and fourth pads 700, 710 and 725 and the second filling structure, and are anisotropically etched. Thus, a third spacer 820 is formed that covers a sidewall of the bit line structure 395 and upper surfaces of portions of the second capping pattern 795 and the second filling pattern 810 in the second filling structure, and a fourth spacer 830 is formed on an outer sidewall of the third spacer 820.

The third spacer 820 includes a nitride, such as silicon nitride, and the fourth spacer 830 includes an oxide, such as silicon oxide.

A dry etching process is performed using the bit line structure 395 and the third and fourth spacers 820 and 830 as an etching mask to form a third opening 440 that exposes an upper surface of the first pad 700.

A fifth spacer layer is formed on upper surfaces of the first capping pattern 385 and the first spacer 820, an outer sidewall of the second spacer 830, an upper surface of a portion of the second filling structure, and the upper surfaces of the first and second pads 700 and 710 exposed by the third opening 440, and the fifth spacer layer is anisotropically etched to form a fifth spacer 840 that covers an outer sidewall of the fourth spacer 830. The fifth spacer 840 also covers an upper surface of a portion of the second filling structure. The fifth spacer 840 includes a nitride, such as silicon nitride.

The third to fifth spacers 820, 830 and 840 that are sequentially stacked on the sidewall of the bit line structure 395 form a preliminary spacer structure 850.

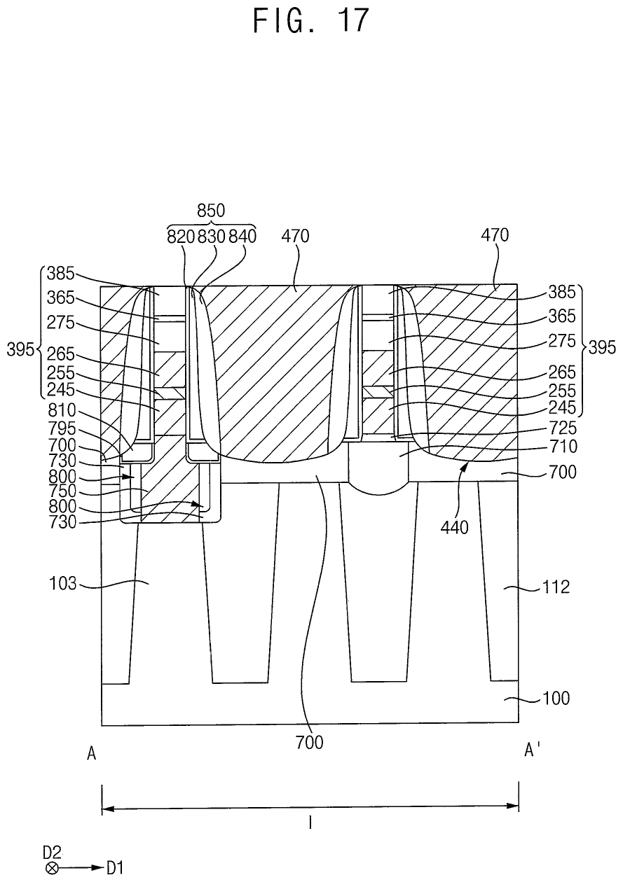

Referring to FIG. 17, in an embodiment, a lower contact plug layer 470 is formed that fills a space between the preliminary spacer structures 850, and is planarized until an upper surface of the first capping pattern 385 is exposed.

In embodiments, the lower contact plug layer 470 extends in the second direction D2, and a plurality of lower contact plug layers 470 are spaced apart from each other in the first direction D1 by the bit line structures 395 and the preliminary spacer structures 850. The lower contact plug layer 470 includes, e.g., doped polysilicon.

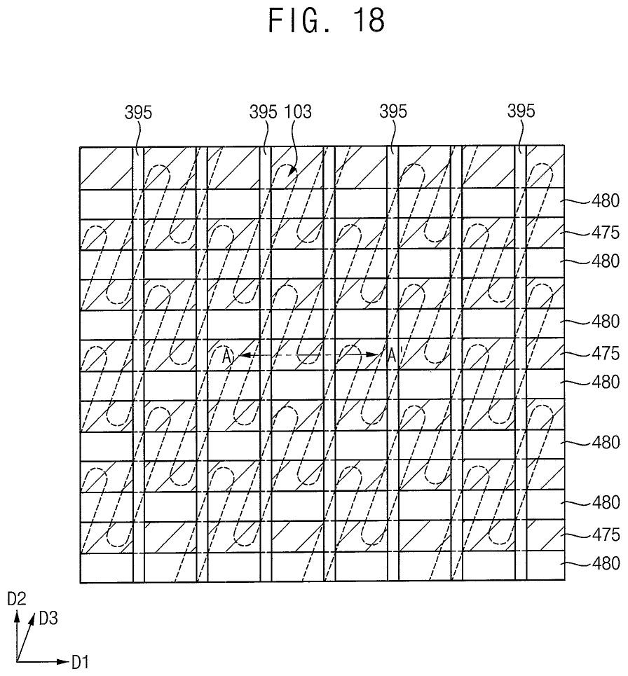

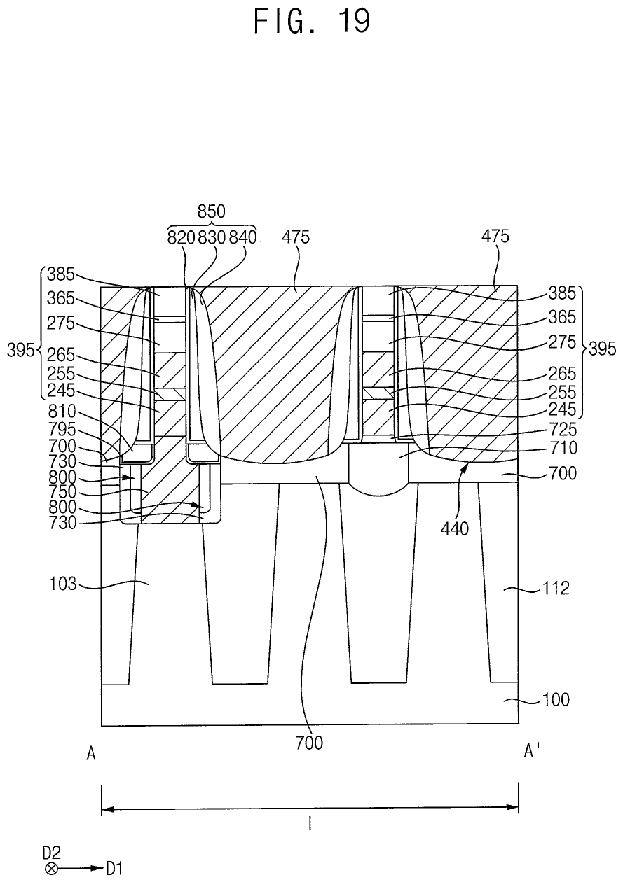

Referring to FIGS. 18 and 19, in an embodiment, a second mask that includes a plurality of fourth openings that extend in the first direction D1 and are spaced apart from each other in the second direction D2 are formed on the first capping pattern 385 and the lower contact plug layer 470, and the lower contact plug layer 470 is etched using the second mask as an etching mask.

In embodiments, each of the fourth openings overlaps the gate structure 170 in a vertical direction. By the etching process, a fifth opening is formed that exposes upper surfaces of the first and second pads 700 and 710 between the bit line structures 395.

After removing the second mask, a third capping pattern 480 is formed on the substrate 100 that fills a space between the preliminary spacer structures 850. The third capping pattern 480 includes a nitride, such as silicon nitride. In embodiments, a plurality of third capping patterns 480 are spaced apart from each other in the second direction D2 and are disposed between the bit line structures 395 that are adjacent in the first direction D1.

Thus, the lower contact plug layer 470 that extends in the second direction D2 between the bit line structures 395 is divided into a plurality of lower contact plugs 475 that are spaced apart from each other in the second direction D2 by the third capping patterns 480.

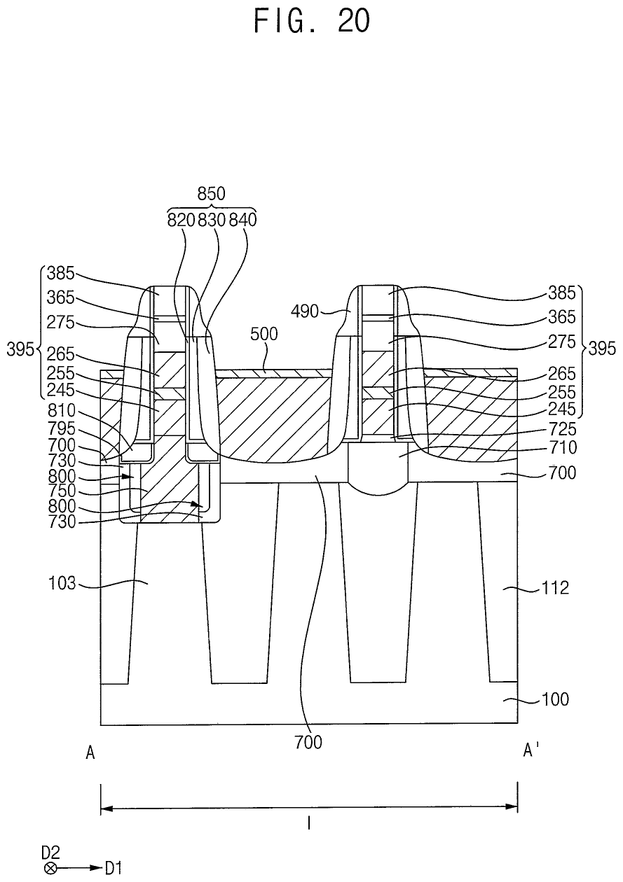

Referring to FIG. 20, in an embodiment, an upper portion of the lower contact plug layer 475 is removed that exposes an upper portion of the preliminary spacer structure 850, and upper portions of the fourth and fifth spacers 830 and 840 of the exposed preliminary spacer structure 850 are removed.

An upper portion of the lower contact plug 475 is removed by, e.g., an etch back process, and the upper portions of the fourth and fifth spacers 830 and 840 are removed by a wet etching process.

A sixth spacer layer is formed on the bit line structure 395, the preliminary spacer structure 850, the third capping pattern 480 and the lower contact plug 475, and the sixth spacer layer is anisotropically etched to form a sixth spacer 490 on an outer sidewall of a portion of the third spacer 820.

The sixth spacer 490 that is formed by the anisotropic etching process covers an upper surface of the fourth spacer 830 and at least a portion of an upper surface of the lower contact plug 475. Thus, during the anisotropic etching process, a portion of the fifth spacer 840 not covered by the sixth spacer 490 is also removed.

In some embodiments, a seventh spacer layer is formed on the bit line structure 395, the third spacer 820, the sixth spacer 490, the lower contact plug 475 and the third capping pattern 480, and the seventh spacer layer is further etched to form a seventh spacer on a sidewall of the sixth spacer 490, and an upper portion of the lower contact plug 475 is etched using the bit line structure 395, the third spacer 820, the sixth spacer 490, the seventh spacer and the third capping pattern 480 as an etching mask. Thus, an upper surface of the lower contact plug 475 is lower than uppermost surfaces of the fourth and fifth spacers 830 and 840.

A metal silicide pattern 500 is formed on the upper surface of the lower contact plug 475. In embodiments, the metal silicide pattern 500 is formed by forming a first metal layer on the bit line structure 395, the third and sixth spacers 820 and 490, the lower contact plug 475 and the second capping pattern 480, performing a heat treatment on the first metal layer to perform a silicidation process in which the first metal layer, which includes a metal, and the lower contact plug 475, which includes silicon, react with each other, and removing an unreacted portion of the first metal layer. A height of an upper surface of the metal silicide pattern 500 that formed by the silicidation process increases.

The metal silicide pattern 500 includes, e.g., at least one of cobalt silicide, nickel silicide, or titanium silicide, etc.

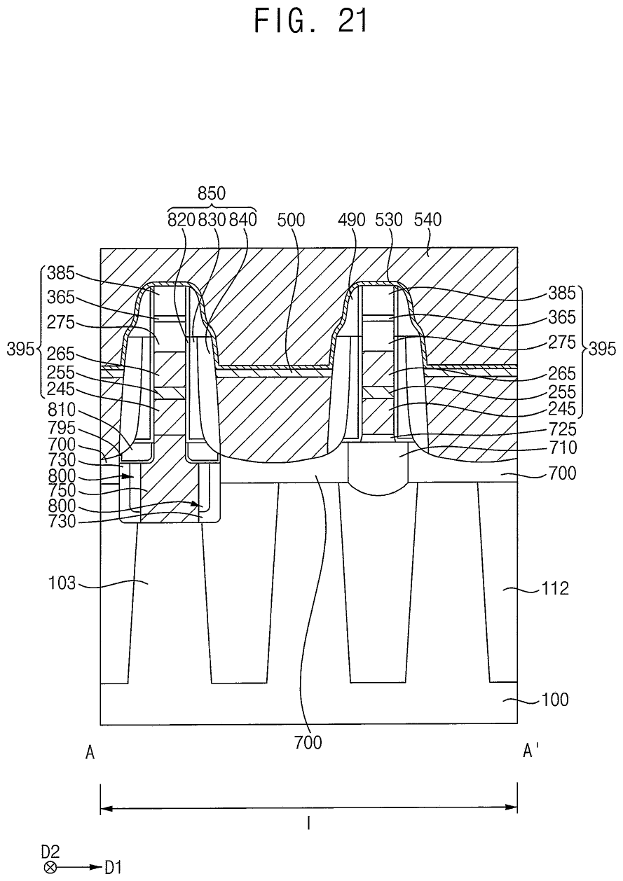

Referring to FIG. 21, in an embodiment, a third barrier layer 530 is formed on the bit line structure 395, the third and sixth spacers 820 and 490, the metal silicide pattern 500 and the third capping pattern 480, and a second metal layer 540 is formed on the third barrier layer 530 that fills a space between the bit line structures 395.

A planarization process is performed on an upper portion of the second metal layer 540. The planarization process includes a CMP process and/or an etch back process.

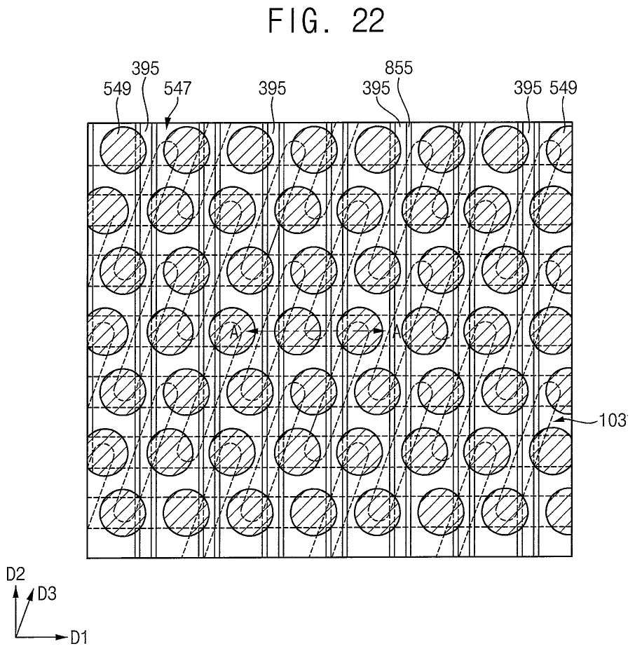

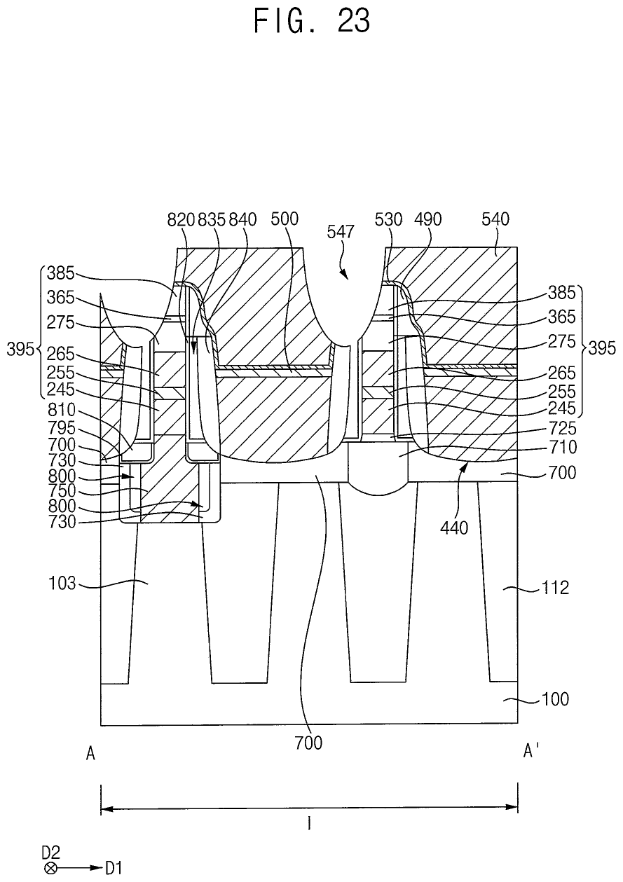

Referring to FIGS. 22 and 23, in an embodiment, the second metal layer 540 and the third barrier layer 530 are patterned to form an upper contact plug 549, and a sixth opening 547 is formed between the upper contact plugs 549.

During the formation of the sixth opening 547, the second metal layer 540, the third barrier layer 530, the insulation structure in the bit line structure 395, the preliminary spacer structure 850 and the sixth spacer 490 on the sidewall of the bit line structure 395, and the third capping pattern 480 are partially removed, and thus an upper surface of the fourth spacer 830 is exposed.

As the sixth opening 547 is formed, the second metal layer 540 and the third barrier layer 530 are transformed into a second metal pattern and a third barrier pattern, respectively, and the third barrier pattern covers a lower surface and a sidewall of the second metal pattern, which forms an upper contact plug 549. In embodiments, a plurality of upper contact plugs 549 are spaced apart from each other in the first and second directions D1 and D2, and are arranged in a honeycomb pattern or a lattice pattern in a plan view. Each of the upper contact plugs 549 has a shape of a circle, an ellipse, or a polygon.

The lower contact plug 475, the metal silicide pattern 500 and the upper contact plug 549 that are sequentially stacked on the substrate 100 form a contact plug structure.

The exposed fourth spacer 830 is removed to form an air gap 835 connected with the sixth opening 547. The fourth spacer 830 is removed by, e.g., a wet etching process.

In embodiments, a portion of the fourth spacer 830 directly exposed by the sixth opening 547 and a portion of the fourth spacer 830 parallel thereto are removed. That is, both the portion of the fourth spacer 830 exposed by the sixth opening 547 and not covered by the upper contact plug 549 and a portion of the fourth spacer 830 covered by the upper contact plug 549 are removed.

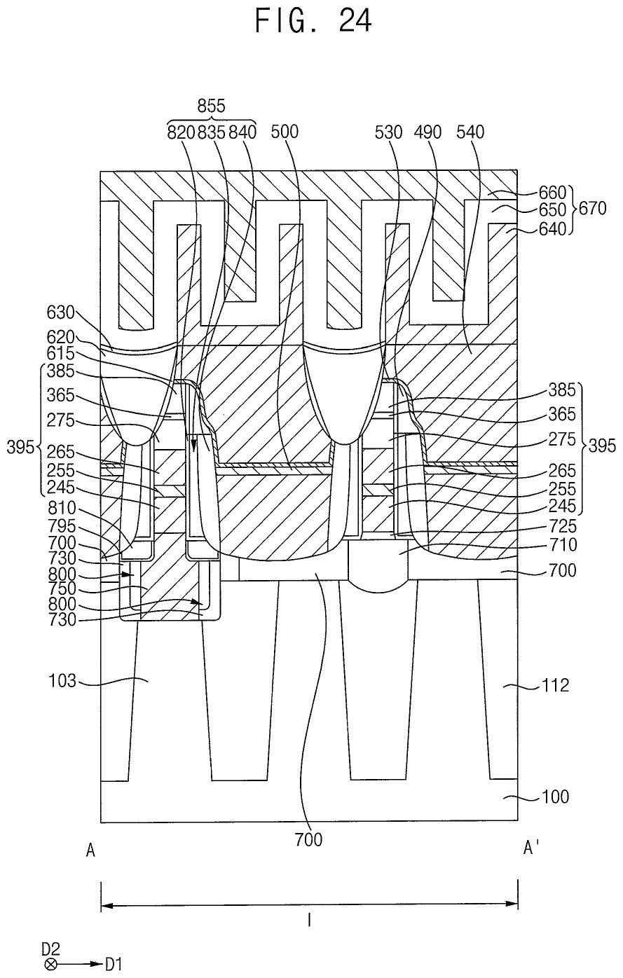

Referring to FIG. 24, in an embodiment, a first insulation pattern 615 is formed on a sidewall of the sixth opening 547, and a second insulation pattern 620 that fills a remaining portion of the sixth opening 547 is formed on the first insulation pattern 615. Thus, a top end of the air gap 835 is closed by the first insulation pattern 610.

The air gap 835 may be referred as a second air spacer 835, and the second, third and fifth spacers 835, 820 and 840 form a spacer structure 855.

The first insulation pattern 615 is formed by forming a first insulation layer on an inner wall of the sixth opening 547, the upper contact plug 549 and the third capping pattern 480, and anisotropically etching the first insulation layer.

The second insulation pattern 620 is formed by forming a second insulation layer on the first insulation pattern 615, the upper contact plug 549 and the third capping pattern 480, and performing an etch back process on the second insulation layer.

Each of the first and second insulation patterns 615 and 620 includes a nitride, such as silicon nitride, and forms an insulation pattern structure.

A second etch stop layer 630 is formed on the first insulation pattern 620, the upper contact plug 549 and the third capping pattern 480, and a mold layer is formed on the second etch stop layer 630. A portion of the mold layer and a portion of the second etch stop layer 630 thereunder are partially etched to form a seventh opening that exposes an upper surface of the upper contact plug 549.

As the plurality of upper contact plugs 549 are spaced apart from each other in the first and second directions D1 and D2, and are arranged in a honeycomb pattern or a lattice pattern in a plan view, the seventh openings that expose the upper contact plugs 549 are also arranged in a honeycomb pattern or a lattice pattern in a plan view.

A lower electrode layer is formed on a sidewall of the seventh opening, the exposed upper surface of the upper contact plug 549 and the mold layer, a second sacrificial layer that fills the seventh opening is formed on the lower electrode layer, and the lower electrode layer and the second sacrificial layer is planarized until an upper surface of the mold layer is exposed to divide the lower electrode layer.

Thus, a lower electrode 640 that has a hollow cylindrical shape is formed in the seventh opening. However, in an embodiment, if a width of the seventh opening is small, the lower electrode 640 has a pillar shape. The lower electrode 640 includes, e.g., at least one of a metal, a metal nitride, a metal silicide, or doped polysilicon, etc.

The second sacrificial layer and the mold layer are removed by, e.g., a wet etching process using, e.g., LAL solution.

A dielectric layer 650 is formed on a surface of the lower electrode 640 and the second etch stop layer 630. The dielectric layer 650 includes, e.g., a metal oxide. In an embodiment, the dielectric layer 650 is conformally formed on the lower electrode 640 and includes an opening in the opening of the hollow cylindrical shaped lower electrode 640.

An upper electrode 660 is formed on the dielectric layer 650. The upper electrode 660 includes, e.g., at least one of a metal, a metal nitride, a metal silicide, or doped silicon-germanium, etc. In an embodiment, the upper electrode 660 includes a first upper electrode that includes a metal or a metal nitride and a second upper electrode that includes doped silicon-germanium. In an embodiment, the first upper electrode extends from the second upper electrode into the opening of the dielectric layer 650, and into a space between adjacent lower electrodes 640.

The lower electrode 640, the dielectric layer 650 and the upper electrode 660 form a capacitor 670.

Upper wirings are further formed on the capacitor 670 to complete the fabrication of the semiconductor device.

As illustrated above, the first and second spacers 730 and 740 are formed on the sidewall of the second opening 230, the first filling pattern 750 is formed to fill the second opening 230, and the upper portions of the first and second spacers 730 and 740 and the upper portion of the first filling pattern 750 that are not covered by the bit line structure 395 are removed. The remaining portion of the second spacer 740 is removed to form the third recess 745, the first sacrificial pattern 780, which includes a pyrolysis material, is formed to fill the third recess 745, and the second capping layer 790 is formed to cover the first sacrificial pattern 780. The first substrate 100 is heated to remove the first sacrificial pattern 780 so that the first air spacer 800 is formed.

Thus, the first air spacer 800 that includes a low-k material such as air is formed between the first filling pattern 750 and the first pad 700, each of which includes a conductive material such as doped polysilicon, and thus parasitic capacitance is reduced.

The upper portion of the first filling pattern 750 not covered by the bit line structure 395 is removed so that the lower portion of the first filling pattern 750 is relatively wide and the upper portion is relatively narrow, and thus the lower portion of the first filling pattern 750 is relatively close to the first pad 700 so that the parasitic capacitance between the lower portion of the first filling pattern 750 and the first pad 700 is relatively large. Thus, the upper portion of the first filling pattern 750 is removed to a depth that is sufficient to decrease the parasitic capacitance. However, in embodiments, the first air spacer 800 is formed that surrounds the lower portion of the first filling pattern 750, and thus the upper portion of the first filling pattern 750 is partially removed because the parasitic capacitance between the lower portion of the first filling pattern 750 and the first pad 700 is low due to the first air spacer 800. Accordingly, a process that removes the upper portion of the first filling pattern 750 is easily performed.

A semiconductor device manufactured by above processes has the following structural characteristics.

Referring to FIGS. 22 and 24, the semiconductor device includes the active pattern 103 on the substrate 100 that extends in the third direction D3; the isolation pattern 112 on the substrate 100 that covers the sidewall of the active pattern 103; the gate structure 170 that extends in the first direction D1 and is buried in the upper portions of the active pattern 103 and the isolation pattern 112; the first pad 700 disposed on the active pattern 103 and the isolation pattern 112 and that includes a conductive material; the second pad 710 disposed on the active pattern 103 and the isolation pattern 112 and that covers the sidewall of the first pad 700 and includes an insulating material; the conductive contact plug 750 that extends in the third direction D3 through the first pad 700, the upper portion of the central portion of the active pattern 103 and the portion of the isolation pattern 112 adjacent thereto, and that includes the lower portion having a first width and the upper portion having a second width narrower than the first width; the bit line structure 395 that extends in the second direction D2 on the conductive contact plug 750 and the first and second pads 700 and 710; the first air spacer 800 and the first spacer 730 that are sequentially stacked in the horizontal direction on the lower sidewall of the conductive contact plug 750; the second capping pattern 795 disposed on the first air spacer 800 and the first spacer 730 and that covers the upper sidewall of the conductive contact plug 750; the second filling pattern 810 disposed on the second capping pattern 795 and that includes an insulating material; the spacer structure 855 disposed on the second capping pattern 795 and the second filling pattern 810 and on the sidewall of the bit line structure 395; the contact plug structure disposed on the first pad 700 on each of opposite end portions in the third direction D3 of the active pattern 103; and the capacitor 670 disposed on the contact plug structure.

In embodiments, the first air spacer 800 directly contacts a sidewall of the lower portion of the conductive contact plug 750.

In embodiments, the fourth pad 725 includes an insulating material and is formed between a portion of the bit line structure 395 under which no conductive contact plug 750 is formed and the first and second pads 700 and 710.

In embodiments, the spacer structure 855 includes the third spacer 820, the second air spacer 835 and the fifth spacer 840 that are sequentially stacked in the horizontal direction from the sidewall of the bit line structure 395.

In embodiments, the second width of the upper portion of the conductive contact plug 750 is substantially equal to a width of a portion of the bit line structure 395 on the upper portion of the conductive contact plug 750.

In embodiments, the first pad 700 overlaps an upper portion of the first air spacer 800 in the horizontal direction.

In embodiments, a lower surface of the first pad 700 is lower than a lower surface of the upper portion of the conductive contact plug 750.

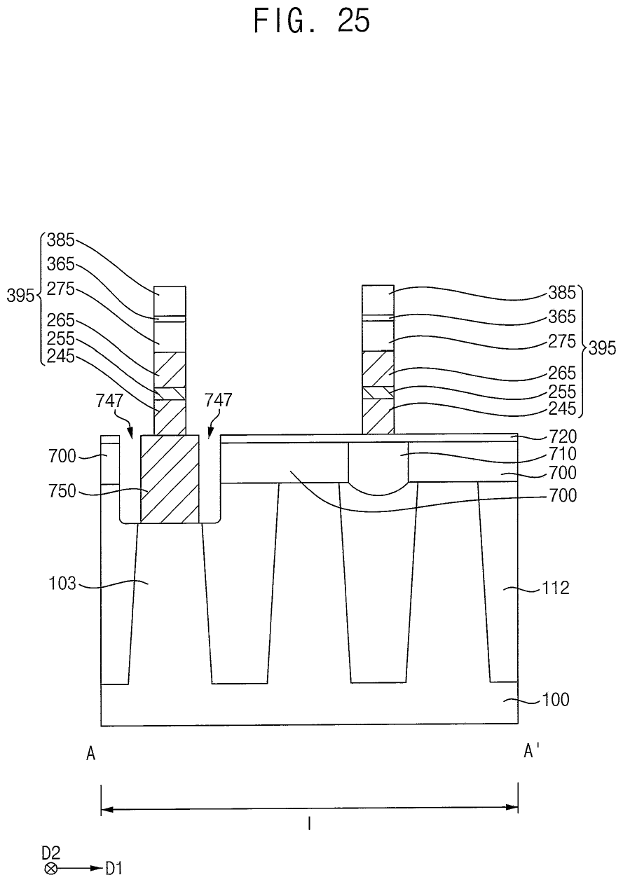

FIGS. 25 to 28 are cross-sectional views that illustrate a method of manufacturing a semiconductor device in accordance with embodiments. This method may include processes substantially the same as or similar to those illustrated with reference to FIGS. 1 to 24, and thus repeated explanations thereof may be omitted herein.

Referring to FIG. 25, in embodiments, processes substantially the same as or similar to those illustrated with reference to FIGS. 1 to 10 are performed, and the first and second spacers 730 and 740 are removed to form an eighth opening 747 that exposes a sidewall of the first filling pattern 750, sidewalls of the first and second pads 700 and 710, and upper surfaces of the active pattern 103 and the isolation pattern 112.

In embodiments, after removing the second spacer 740, the first spacer 730 is removed. The first spacer 730 includes, e.g., silicon oxycarbide, and can be removed by, e.g., an ashing process.

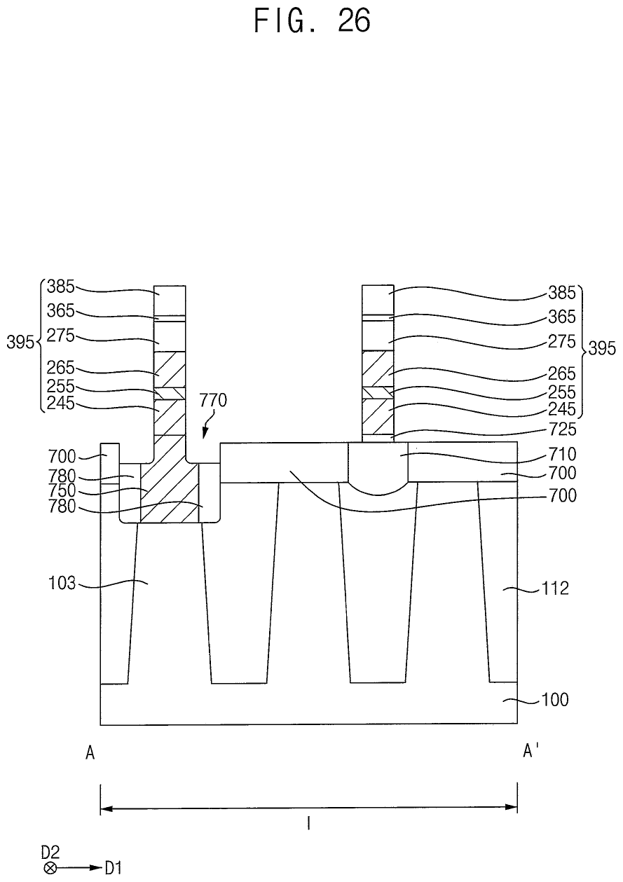

Referring to FIG. 26, in an embodiment, after forming the first sacrificial pattern 780 in the eighth opening 747, an upper portion of the first sacrificial pattern 780 is removed to form a sixth recess, and thus a sidewall of an upper portion of the first filling pattern 750 is exposed.

The upper portion of the first filling pattern 750 not covered by the bit line structure 395 but exposed by the sixth recess is removed by an etching process, and thus the first filling pattern includes a relatively wide lower portion and a relatively narrow upper portion.

During the etching process, a portion of the third pad 720 that is higher than an upper surface of the first sacrificial pattern 780 and not covered by the bit line structure 395 is also removed.

Thus, the fourth recess 770 is formed in an upper portion of the initial second opening 230, and the fourth pad 725 is formed under a portion of the bit line structure 395 outside of the second opening 230. Accordingly, the upper surfaces of the first and second pads 700 and 710 are exposed.

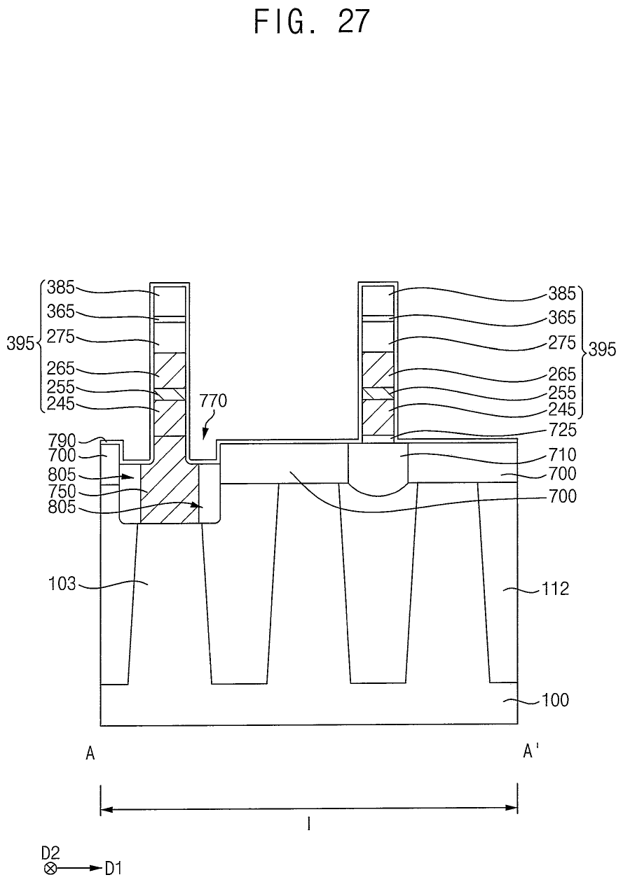

Referring to FIG. 27, in an embodiment, the second capping layer 790 is formed on the bit line structure 395, the first filling pattern 750, the first sacrificial pattern 780, and the first, second and fourth pads 700, 710 and 725 by, e.g., an ALD process, and the substrate 100 is heated to remove the first sacrificial pattern 780. Thus, a third air spacer 805 that includes air is formed between the first filling pattern 750, the second capping layer 790, the first and second pads 700 and 710, the active pattern 103 and the isolation pattern 112. The third air spacer 805 has a greater volume than the first air spacer 800 of FIG. 14.

In embodiments, the third air spacer 805 is surrounded by the first filling pattern 750, i.e., the conductive contact plug, the active pattern 103, the isolation pattern 112 and the second capping pattern 795.

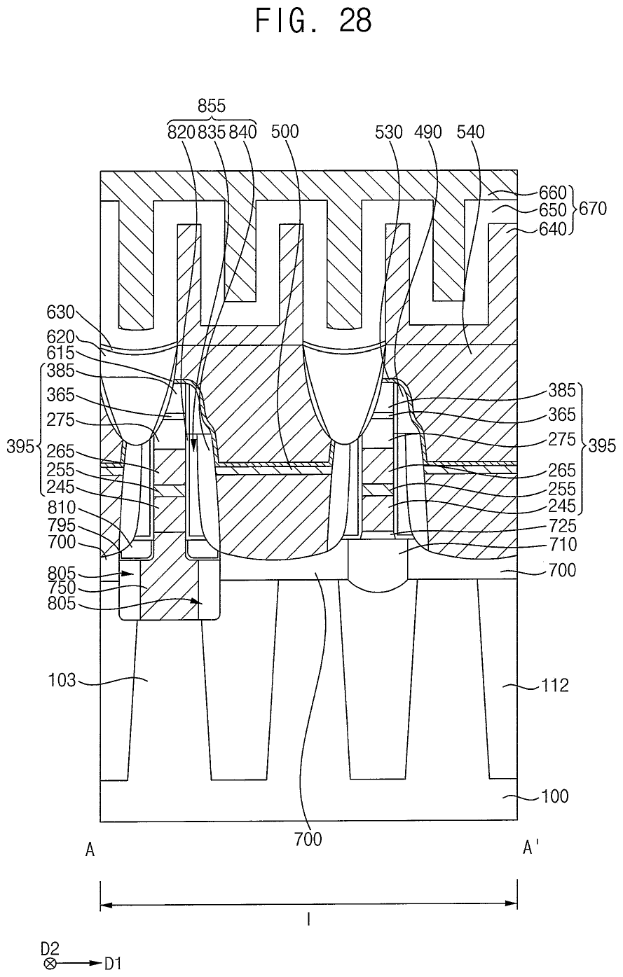

Referring to FIG. 28, in embodiments, processes substantially the same as or similar to those illustrated with reference to FIGS. 15 to 24 are performed to complete the fabrication of the semiconductor device.

As illustrated above, the first spacer 730 includes, e.g., silicon oxycarbide, that is removed by an ashing process, and thus the removal of the first spacer 730 does not affect neighboring structures. Accordingly, not only the second spacer 740 but also the first spacer 730 are removed so that the third air spacer 805 has a greater volume than the first air spacer 800, which increases the reduction of the parasitic capacitance between the first filling pattern 750 and the first pad 700.

While embodiments of the present inventive concepts have been shown and described with reference to the drawings, it will be understood by those of ordinary skill in the art that various changes in form and details may be made thereto without departing from the spirit and scope of embodiments of the present inventive concepts as set forth by the following claims.

What is claimed is:

1. A semiconductor device, comprising:
a conductive contact plug disposed on a substrate, wherein the conductive contact plug includes a lower portion and an upper portion thereon, wherein the lower portion has a first width and the upper portion has a second width less than the first width;
a bit line structure disposed on the conductive contact plug, wherein the bit line structure includes a conductive structure and an insulation structure that are stacked in a vertical direction that is substantially perpendicular to an upper surface of the substrate;
first and second spacers stacked on a sidewall of the lower portion of the conductive contact plug in a horizontal direction substantially parallel to the upper surface of the substrate; and
a capping pattern disposed on the first and second spacers, wherein the capping pattern covers a sidewall of the upper portion of the conductive contact plug,
wherein the first spacer directly contacts the sidewall of the lower portion of the conductive contact plug and includes air.

2. The semiconductor device according to claim 1, wherein the conductive contact plug includes doped polysilicon.

3. The semiconductor device according to claim 1, wherein the second width of the upper portion of the conductive contact plug is substantially equal to a width of a portion of the bit line structure on the upper portion of the conductive contact plug.

4. The semiconductor device according to claim 1, further comprising an active pattern and an isolation pattern disposed on the substrate, wherein the isolation pattern covers a sidewall of the isolation pattern,
wherein the conductive contact plug contacts a central upper surface of the active pattern.

5. The semiconductor device according to claim 4, further comprising a conductive pad disposed on the active pattern and the isolation pattern, wherein the conductive pad overlaps at least a portion of the conductive contact plug in the horizontal direction.

6. The semiconductor device according to claim 5, wherein the conductive pad overlaps an upper portion of the first spacer in the horizontal direction.

7. The semiconductor device according to claim 5, wherein a lower surface of the conductive pad is lower than a lower surface of the upper portion of the conductive contact plug.

8. The semiconductor device according to claim 1, further comprising:
an insulation pattern disposed on the capping pattern; and
a spacer structure disposed on the capping pattern and the insulation pattern, wherein the spacer structure covers a sidewall of the bit line structure.

9. A semiconductor device, comprising:
a conductive contact plug disposed on a substrate, wherein the conductive contact plug includes a lower portion and an upper portion thereon, wherein the lower portion has a first width and the upper portion has a second width narrower than the first width;
a bit line structure disposed on the conductive contact plug, wherein the bit line structure includes a conductive structure and an insulation structure stacked in a vertical direction that is substantially perpendicular to an upper surface of the substrate;
an air spacer that directly contacts a sidewall of the lower portion of the conductive contact plug and that includes air; and
a capping pattern disposed on a top end of the air spacer.

10. The semiconductor device according to claim 9, further comprising an active pattern and an isolation pattern disposed on the substrate, wherein the isolation pattern covers a sidewall of the isolation pattern,
wherein the conductive contact plug contacts a central upper surface of the active pattern.

11. The semiconductor device according to claim 10, further comprising a conductive pad disposed on the active pattern and the isolation pattern, wherein the conductive pad overlaps at least a portion of the conductive contact plug in the horizontal direction.

12. The semiconductor device according to claim 11, wherein the conductive pad overlaps an upper portion of the air spacer in the horizontal direction.

13. The semiconductor device according to claim 11, wherein a sidewall of the conductive pad directly contacts the air spacer.

14. The semiconductor device according to claim 11, wherein the air spacer is surrounded by the conductive contact plug, the active pattern, the isolation pattern and the capping pattern.

15. A semiconductor device, comprising:
an active pattern disposed on a substrate;
an isolation pattern disposed on the substrate, wherein the isolation pattern covers a sidewall of the active pattern;
a gate structure that extends in a first direction substantially parallel to an upper surface of the substrate, wherein the gate structure is disposed in upper portions of the active pattern and the isolation pattern;
a conductive pad disposed on the active pattern and the isolation pattern;
a conductive contact plug that extends through the conductive pad and contacts a central upper surface of the active pattern, wherein the conductive contact plug includes a lower portion and an upper portion thereon, and the lower portion has a first width and the upper portion has a second width that is narrower than the first width;
a bit line structure disposed on the conductive contact plug and the conductive pad, wherein the bit line structure extends in a second direction substantially parallel to the upper surface of the substrate and substantially perpendicular to the first direction;
first and second spacers stacked on a sidewall of the lower portion of the conductive contact plug in a horizontal direction substantially parallel to the upper surface of the substrate;
a capping pattern disposed on the first and second spacers, wherein the capping pattern covers a sidewall of the upper portion of the conductive contact plug;
an insulation pattern disposed on the capping pattern;
a spacer structure disposed on the capping pattern and the insulation pattern, wherein the spacer structure is disposed on a sidewall of the bit line structure;
a contact plug structure disposed on the conductive pad; and
a capacitor disposed on the contact plug structure,
wherein the first spacer directly contacts the sidewall of the lower portion of the conductive contact plug and includes air.

16. The semiconductor device according to claim 15, further comprising a first insulation pad interposed between the conductive pad and the bit line structure.

17. The semiconductor device according to claim 16, further comprising a second insulation pad disposed on the active pattern and the isolation pattern, wherein the second insulation pad covers a sidewall of the conductive pad,
wherein the first insulation pad is disposed on the conductive pad and the second insulation pad.

18. The semiconductor device according to claim 15, wherein the spacer structure includes third, fourth and fifth spacers that are sequentially stacked on the sidewall of the bit line structure, and
wherein the fourth spacer includes air.

19. The semiconductor device according to claim 15, wherein:
the active pattern extends in a third direction substantially parallel to the upper surface of the substrate and having an acute angle with the first and second directions,
the conductive pad is disposed on a central upper surface of the active pattern and each of opposite end portions in the third direction of the active pattern, and
the contact plug is disposed on a portion of the conductive pad on each of opposite end portions in the third direction of the active pattern.

20. The semiconductor device according to claim 15, wherein the conductive pad overlaps an upper portion of the first spacer in the horizontal direction.
